(19) United States
(12) Patent Application Publication
(10) Pub. No.: US 2025/0102606 A1
(43) Pub. Date: Mar. 27, 2025

(54) Acquisition of Measurement Data Using Magnetic Resonance with Magnetization Preparation

(71) Applicant: Siemens Healthineers AG, Forchheim (DE)

(72) Inventors: Patrick Liebig, Erlangen (DE); Moritz Zaiss, Nürnberg (DE)

(73) Assignee: Siemens Healthineers AG, Forchheim (DE)

(21) Appl. No.: 18/892,784

(22) Filed: Sep. 23, 2024

(30) Foreign Application Priority Data
Sep. 25, 2023 (DE) 10 2023 209 345.6

(51) Int. Cl. G01R 33/56; G01R 33/24

(52) U.S. Cl. CPC G01R 33/5605; G01R 33/246; G01R 33/5608

(57) ABSTRACT

Techniques are described for acquiring measurement data of an object under examination positioned in a magnetic resonance system using magnetic resonance with magnetization preparation. The techniques include performing a magnetization preparation block, applying at least two further preparation RF pulses, after the end of the magnetization preparation block, performing an acquisition block which comprises at least one further RF pulse and during which at least two echo signals are each acquired as measurement data, wherein at least one of the at least two echo signals is generated by the at least two further preparation RF pulses and the further RF pulse, and storing and/or further processing the acquired measurement data.

### CROSS-REFERENCE TO RELATED APPLICATIONS

The present application claims priority to and the benefit of Germany patent application no. DE 10 2023 209 345.6, filed on Sep. 25, 2023, the contents of which are incorporated herein by reference in their entirety.

### TECHNICAL FIELD

The disclosure relates to an improved method for acquiring measurement data using magnetic resonance technology with magnetization preparation and contrast correction and, in particular, to an improved CEST (Chemical Exchange Saturation Transfer) technique.

### BACKGROUND

Magnetic resonance technology (hereinafter abbreviated to MR) is a well-known technology for generating images of the interior of an object under examination. In simple terms, the object under examination is positioned in a magnetic resonance device in a comparatively strong, static, homogeneous main magnetic field, also known as the B0 field, with field strengths of 0.2 to 7 Tesla or more, so that its nuclear spins are oriented along the main magnetic field. To trigger nuclear spin resonances that can be measured as (MR) signals, radiofrequency excitation pulses (RF pulses) are applied to the object under examination, the triggered nuclear spin resonances are measured as so-called k-space data and MR images are reconstructed or spectroscopy data is determined based on this data. The alternating magnetic field generated by the excitation pulses applied by means of a transmit coil is also referred to as the B1 field. To spatially encode the measurement data, rapidly switched magnetic gradient fields, or gradients for short, are superimposed on the main magnetic field. A scheme used that describes a chronological order of RF pulses to be applied and gradients to be switched is referred to as a pulse sequence (scheme), or sequence for short. The acquired measurement data is digitized and stored as complex numerical values in a k-space matrix. A corresponding MR image can be reconstructed from the k-space matrix populated with values, e.g. by means of a multidimensional Fourier transform.

In MR imaging, the so-called CEST effect (Chemical Exchange Saturation Transfer) can be utilized to indirectly detect certain substances (e.g. creatine, glycogen, glutamate) by transferring saturated exchangeable bonds of these substances e.g. to water. This makes it possible, for example, to assess and evaluate the quality of cartilage in a human subject more effectively than with other methods.

The method is based on the concept that e.g. proteins and other macromolecules can absorb RF energy at frequencies that are a few hundred Hz to a few thousand Hz removed from pure water resonance. When an “off-resonance” RF excitation pulse of this kind is applied, the energy absorbed by such macromolecules is transferred to the water molecules through chemical exchange and dipolar interactions, thereby reducing their signal, which is why the term off-resonance saturation is also often used.

CEST thus utilizes the transfer of magnetization by chemical exchange. The resonances of labile protons, which are bound in the molecules of the substance to be detected and measurable as MR signals, are saturated to subsequently detect these protons when they are bound to water molecules to which they have been transferred by chemical exchange. To be able to detect specific substances, a series of acquisitions is made in which the labile protons are excited with different off-resonant frequencies. The article by Zijl et al. “Chemical Exchange Saturation Transfer (CEST): What is in a Name and What Isn't?”; Magn. Reson. Med. 65: pp. 927-948, 2011, provides an overview of the CEST technique.

Since CEST imaging requires a plurality of acquisitions using different frequency offsets (relative to a resonance frequency, e.g. the resonance frequency of water), this technique is already inherently somewhat measurement time intensive, i.e. the measurement times are relatively long and can take e.g. several minutes in total-some 2 to 10 minutes or even more-depending on the application.

In a magnetic resonance system, the measurable volume of an MRI acquisition is limited in all three spatial directions due to physical and technical conditions, such as limited magnetic field homogeneity and non-linearity of the gradient field. An imaging volume, a so-called “field of view” (FoV), is therefore limited to a volume in which the above-mentioned physical characteristics are within a specified tolerance range and thus a true-to-original representation of the object under examination is possible using standard measurement sequences. The therefore limited field of view is particularly limited in the x- and y-directions, i.e. perpendicular to the longitudinal axis of a tunnel of the magnetic resonance system, and is significantly smaller than the volume defined by the annular tunnel of the magnetic resonance system. In conventional magnetic resonance systems, for example, the diameter of the annular tunnel is approximately 60 cm, whereas the diameter of the commonly used field of view, in which the above-mentioned physical characteristics are within the tolerance range, is approximately 50 cm.

However, CEST techniques are particularly sensitive to possible changes and inhomogeneities in the main magnetic field B0 or in the applied alternating field B1 that are residual or produced by the object under examination itself. Such changes can potentially result in serious loss of contrast, making the obtained CEST images unusable for clinical use.

Techniques are already known that create B0 field maps and/or B1 field maps from separately acquired MR signals to use these for contrast correction of the measurement data acquired using CEST technology. Examples of such techniques are described, for example, in the article by Schuenke et al. “Simultaneous Mapping of Water Shift and B1 (WASABI)-Application to Field-Inhomogeneity Correction of CEST MRI Data”, Magn. Reson. Med. 77: pp. 571-580, 2017, the article by Kim et al, “Water Saturation Shift Referencing (WASSR) for Chemical Exchange Saturation Transfer (CEST) Experiments”, Magn. Reson. Med. 61: pp. 1441-1450, 2009, or the article by Windschuh et al. “Correction of B1-inhomogeneities for relaxation-compensated CEST imaging at 7T”, NMR Biomed. 28: pp. 529-537, 2015.

However, the acquisition of static B0 and/or B1 field maps necessary for these methods extends still further the overall measurement time required, which reduces the attractiveness of these methods. They are also unsuitable for responding to dynamic changes in the B0/B1 fields.

### SUMMARY

The object of the disclosure is to provide robust and fast acquisition of magnetization-prepared measurement data, such as CEST acquisitions, without significantly extending the measurement times and with improved quality.

The object is achieved by a method for acquiring measurement data of an object under examination positioned in a magnetic resonance system using magnetic resonance with magnetization preparation as described in the various embodiments herein, including the claims.

A method according to the disclosure for acquiring measurement data of an object under examination positioned in a magnetic resonance system using magnetic resonance with magnetization preparation comprises the following steps:
a) Performing a magnetization preparation block,
b) Applying at least two further preparation RF pulses,
c) After the end of the magnetization preparation block, performing an acquisition block which comprises at least one further RF pulse and during which at least two echo signals are each acquired as measurement data, wherein at least one of the at least two echo signals is generated by the at least two further preparation RF pulses and the further RF pulse,
d) Storing and/or further processing the acquired measurement data.

By generating and acquiring at least two echo signals in an acquisition block after a magnetization preparation block, a signal-to-noise ratio (SNR) in image data reconstructed from the acquired measurement data can already be improved. In addition, further information, e.g. field maps of the B0 and/or B1 fields present during the measurement, can be obtained from the measurement data inventively acquired from at least two echo signals, and this information can be used to improve still further the quality e.g. of image data reconstructed from the measurement data without the need for further measurements. This reduces the overall time required for acquiring measurement data and other desired information, such as B0 and/or B1 field maps.

A magnetic resonance system according to the disclosure comprises a magnet unit, a gradient unit, a radiofrequency unit, and a control facility comprising a preparation control unit and designed to carry out a method according to the disclosure.

A computer program according to the disclosure implements a method according to the disclosure on a control facility when it is executed on the control facility. For example, the computer program comprises instructions which, when the program is executed by a control facility, e.g. a control facility of a magnetic resonance system, cause said control facility to carry out a method according to the disclosure. The control facility can take the form of a computer.

Said computer program can also be in the form of a computer program product which is directly loadable into a memory of a control facility and has program code means for carrying out a method according to the disclosure when the computer program product is executed in a computing unit of the computing system.

A computer-readable storage medium according to the disclosure comprises instructions which, when executed by a control facility, e.g. a control facility of a magnetic resonance system, cause the control facility to carry out a method according to the disclosure.

The computer-readable storage medium can be designed as an electronically readable data carrier which has, stored thereon, electronically readable control information which comprises at least one computer program according to the disclosure and is designed such that, when the data carrier is used in a control facility of a magnetic resonance system, it carries out a method according to the disclosure.

The advantages and embodiments recited with respect to the method also apply analogously to the magnetic resonance system, the computer program product, and the electronically readable data carrier.

Further advantages and details of the present disclosure will emerge from the exemplary embodiments described below and from the drawings. The examples given do not constitute a limitation of the disclosure.

### BRIEF DESCRIPTION OF THE DRAWINGS

Further advantages and details of the present disclosure may be recognized from the embodiments described below as well as the drawings. The figures show:

FIG. 1 illustrates a schematic flowchart of an example method, according to one or more embodiments of the present disclosure;

FIG. 2 illustrates a highly schematic representation of a portion of an example pulse sequence diagram for acquiring measurement data, according to one or more embodiments of the present disclosure; and

FIG. 3 illustrates an example magnetic resonance system, according to one or more embodiments of the present disclosure.

### DETAILED DESCRIPTION OF THE DISCLOSURE

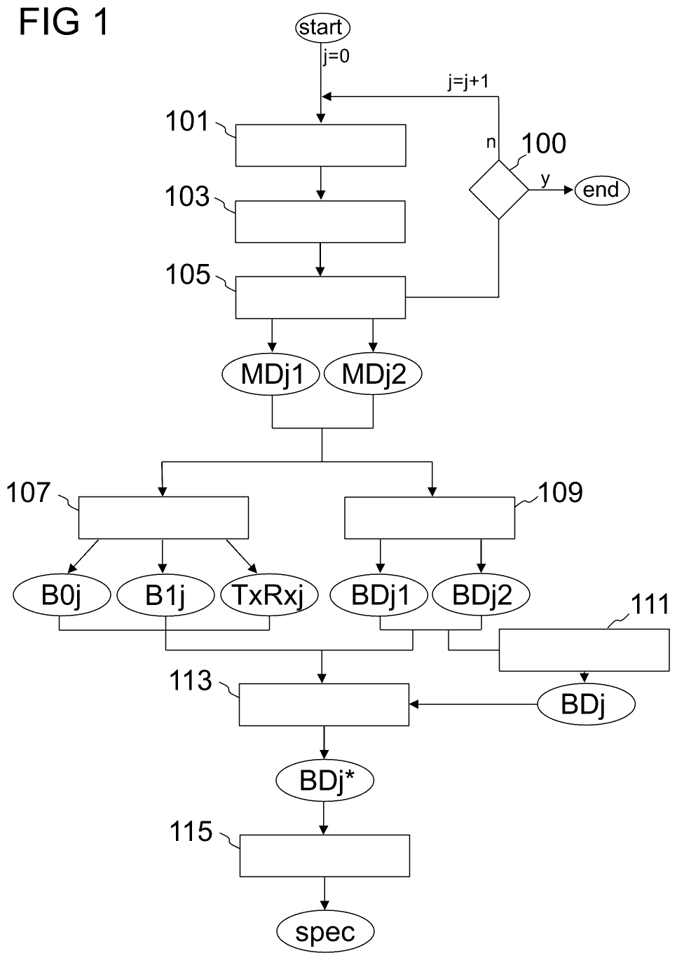

FIG. 1 illustrates a flowchart of an example method according to the disclosure whereby magnetic resonance with magnetization preparation is used to acquire measurement data of an object under examination positioned in a magnetic resonance system.

After selecting a desired magnetization preparation (j=0), a magnetization preparation block is performed (block 101). As a rule, RF pulses are applied to the object under examination, and gradients are switched to generate the desired magnetization preparation, which may include the use of any suitable techniques, including doing so in a known manner. The magnetization preparation can, for example, be a preparation for a magnetization transfer (MT) technique, such as MPRAGE (Magnetization Prepared Rapid Gradient Echo Imaging) or a CEST technique with preparation of a desired off-resonance saturation. In the latter case, the magnetization preparation block performed is a CEST preparation block.

At least two further preparation RF pulses are applied (block 103). The application of the at least two further preparation RF pulses can take place, for example, immediately after performing the magnetization preparation block. It is also conceivable for the application of the at least two further preparation RF pulses to be interleaved with the magnetization preparation block performed.

On completion of the magnetization preparation block, an acquisition block is performed (block 105), which comprises at least one further RF pulse and during which at least two echo signals are acquired as measurement data MDj1, MDj2, at least one of the at least two echo signals being generated by the at least two further preparation RF pulses and the further RF pulse.

The acquired measurement data MDj1, MDj2 are stored and can be further processed.

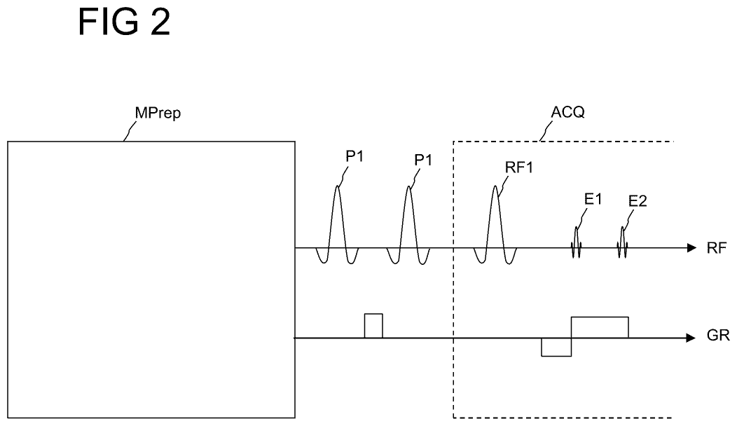

FIG. 2 is a highly schematic representation of part of a pulse sequence scheme for acquiring measurement data in the manner according to the disclosure. An upper line RF shows RF pulses to be applied and echo signals generated according to the disclosure. The lower line GR shows examples of gradients switched in the readout direction.

A magnetization preparation block MPrep with e.g. known RF pulses and gradients is followed by two further preparation RF pulses P1 in the illustration in FIG. 2. These additional preparation RF pulses P1 can also be incorporated into the magnetization preparation block MPrep if the desired magnetization preparation permits this.

The magnetization preparation block MPRep and the two further preparation RF pulses P1 are followed by an acquisition block ACQ, which comprises at least one further RF pulse RF1, and in which at least two echo signals E1, E2 are detected and acquired as measurement data. At least one of the at least two echo signals E1, E2 is generated by the at least two further preparation RF pulses P1 and the further RF pulse RF1. For example, one of the at least two echo signals E1, E2 acquired as measurement data can be a stimulated echo signal generated by the at least two further preparation RF pulses P1 and the further RF pulse RF1. To generate a stimulated echo signal, a gradient can be switched between the further preparation RF pulses, as is known, for example, from the Stimulated Echo Acquisition Method (STEAM).

One of the at least two echo signals E1, E2 acquired as measurement data can be an echo signal of a free induction decay (FID) generated by the additional RF pulse RF1.

A B0 field map B0j and/or a B1 field map B1j and/or a field map of a phase of a transmit-receive chain of the acquired measurement data TxRxj can be determined from the measurement data MDj1, MDj2 of the at least two acquired echo signals (block 107).

Possible determinations of such field maps from measurement data acquired in an acquisition block from a stimulated echo signal and an FID signal are described, for example, in the article by Nehrke and Börnert “DREAM-A Novel Approach for Robust, Ultrafast, Multislice B1 Mapping”, Magn. Reson. Med. 68: pp. 1517,1526, 2012.

A B0 field map B0j can be determined, for example, from the polar angle of the complex signal FID of the acquired measurement data of the one echo signal and the conjugate complex signal STE* of the acquired measurement data of the other echo signal, so that e.g. the following evaluation applies:

$${ϕ}_{B 0} = angle ( FID \cdot {STE}^{*} ) . \qquad ( 1 )$$

A B1 field map B1j can be calculated e.g. from the cotangent of the square root of the quotient of twice the magnitude of the complex signal STE of the acquired measurement data of the other echo signal and the magnitude of the complex signal FID of the acquired measurement data of the one echo signal divided by the flip angle FAPI of the (first) further preparation RF pulse P1, so that e.g. the following evaluation applies:

$$rB 1 = {tan}^{- 1} ( \sqrt{( \frac{2 \vert STE \vert}{\vert FID \vert} )} ) / {FA}_{P 1} . \qquad ( 2 )$$

A field map of a phase of a transmit-receive chain of the acquired measurement data TxRxj can be determined e.g. from the polar angle of the complex signal FID of the acquired measurement data of the one echo signal and the complex signal STE of the acquired measurement data of the other echo signal, so that e.g. the following evaluation applies:

$${Φ}_{tx / rx} = angle ( FID \cdot STE ) . \qquad ( 3 )$$

Image data BDj1, BDj2 can be reconstructed from the measurement data MDj1, MDj2 of the at least two acquired echo signals (block 109). This can be done in a known manner, e.g. in the usual way for such reconstructions.

The image data BDj1, BDj2 reconstructed from the measurement data MDj1, MDj2 of the at least two acquired echo signals can be combined to form combined image data BDj (block 111). Alternatively, it is also conceivable to first determine combined measurement data from the measurement data of the at least two acquired echo signals and to reconstruct combined image data BDj from the combined measurement data. Determining combined measurement data or combined image data BDj can, for example, include a suitable averaging method and, if necessary, normalizing the measurement data or image data to be combined. Combining measurement data or image data in this way can increase the SNR and thus the quality of the final image data.

For example, for a magnetization preparation j, a combined image BDj can be determined as half the sum of the magnitudes of the normalized signals of the respective echo signals FID(j) and STE(j), so that e.g. the following evaluation applies:

$$BDj = 0.5 \cdot ( \frac{\vert FID ( j ) \vert}{\vert FID ( k ) \vert} + \frac{\vert STE ( j ) \vert}{\vert STE ( k ) \vert} ) , \qquad ( 4 )$$

where |FID(k)| and |STE(k)| are normalization factors.

In the case of a CEST preparation block as a magnetization preparation block performed using different off-resonance saturations j, it is conceivable, for example, to select as normalization factors the signals of the corresponding echo signals having the largest frequency offset with respect to the water resonance frequency, i.e. with the off-resonance saturation j that has the largest offset with respect to the water resonance frequency.

By means of a field map B0j, B1j and/or TxRxj determined from the measurement data MDj1, MDj2 of the at least two acquired echo signals, contrast correction of image data BD1j, BD2j and/or combined image data BDj reconstructed from the acquired measurement data can be performed, whereby corrected image data BDj* is determined (block 113). If the reconstructed image data BD1j and BD2j have been individually corrected to provide corrected image data BDj*, combined corrected image data BDj* can in turn be determined from the respective corrected image data by means of a suitable calculation, such as suitable averaging.

Such contrast corrections based on B0, B1 or TxRx field maps are generally known, e.g. as mentioned in the introduction to the description.

It is possible to perform the blocks 101 to 105 multiple times. For instance, the blocks 101 to 105 can be repeated at least once, wherein a magnetization preparation block performed during a repetition results in a magnetization preparation that is different from one already performed. For this purpose, a query 100 can check after the end of an acquisition block from block 105 whether all the desired magnetization preparations j have already been performed and corresponding measurement data MD1j, MD2j have been acquired. If measurement data MD1j, MD2j with all desired magnetization preparations j have already been acquired, the acquisition of measurement data concludes (“end”). If measurement data MD1j, MD2j have not yet been acquired for all the desired magnetization preparations j, another desired magnetization preparation is selected (j=j+1) and the process re-commences at block 101, wherein a magnetization preparation block corresponding to the new selected magnetization preparation is performed.

In this way, measurement data MD1j, MD2j can be acquired for different magnetization preparations j. For example, in the case of a CEST preparation block as a magnetization preparation block, different off-resonance saturations can be performed and thus different frequency offsets can be examined.

Contrast correction in block 113 can advantageously be performed on the image data reconstructed from the measurement data from which the field map was also determined. In other words, the image data BDj, BD1j, BD2j are each corrected on the basis of field maps that were themselves determined from the measurement data MD1j, MD2j from which the image data BD1j, BD2j and/or BDj were also reconstructed. In this way, the field maps for the contrast correction are each based on the same measurement data MD1j, MD2j as the image data BD1j, BD2j, BDj to be corrected, which makes it possible to also take dynamic effects into account. Particularly high-quality correction that is always adapted to suit current conditions is therefore achieved without the need for separate measurements to determine the field maps, which would result in an increase in the total measurement time required.

If CEST preparation blocks with different off-resonance saturation j have been performed as magnetization preparation blocks, a CEST spectrum can be determined on the basis of the acquired measurement data MD1j, MD2j. For example, the CEST spectrum can be generated based on corrected image data BDj* reconstructed from the measurement data MD1j, MD2j, thereby removing or at least reducing interfering effects of B0 and/or B1 field inhomogeneities in the resulting CEST spectrum, so that the CEST spectrum obtained is of particularly good quality.

By generating and acquiring as measurement data at least two echo signals after a magnetization preparation, the method according to the disclosure allows the quality of the measurement data obtained to be improved. On the one hand, this is already achieved by the increased number of echo signals. On the other hand, measurement data acquired according to the disclosure allows field maps to be determined which can be used to correct the measurement data itself or image data reconstructed from the measurement data in order to be able to correct interfering effects of fluctuations or inhomogeneities in the respective fields without the need for a separate measurement as was previously the case.

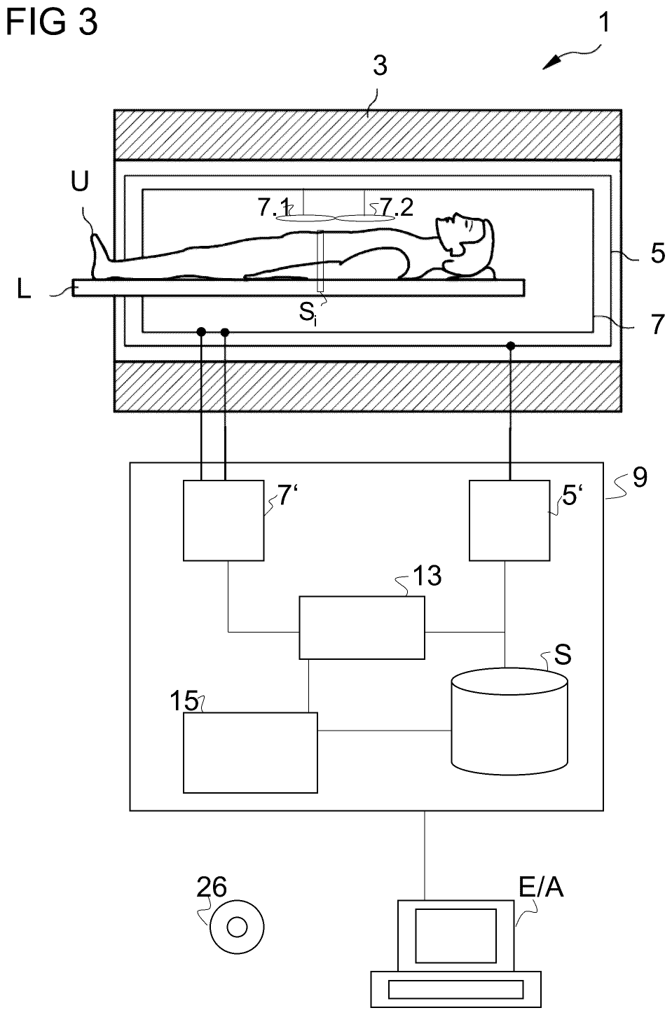

FIG. 3 schematically illustrates a magnetic resonance system 1 according to the disclosure. This comprises a magnetic unit 3 (e.g. a main magnet) for generating the main magnetic field, a gradient unit 5 (e.g. gradient control circuitry) for generating the gradient fields, a radiofrequency unit 7 (e.g. radiofrequency control circuitry) for applying and receiving radiofrequency signals, and a control facility 9 (e.g. a controller, processing circuitry, one or more processors, etc.) configured to carry out any of the methods according to the disclosure.

In FIG. 3, these sub-units of the magnetic resonance system 1 are shown in schematic form by way of example and not limitation. For instance, the radiofrequency unit 7 may comprise a plurality of sub-units, e.g. a plurality of coils such as the coils 7.1 and 7.2 as shown schematically, or more coils, which can be designed either only for transmitting radiofrequency signals. or only for receiving the triggered radiofrequency signals, or for both.

To examine an object under examination U, such as patient or even a phantom, the object under examination U can be positioned on a table L and moved into the measurement volume of the magnetic resonance system 1. The slice or slab Si represents an exemplary target volume of the object under examination, from which echo signals are to be acquired and captured as measurement data.

The control facility 9 is used to control the magnetic resonance system 1 and can, for instance, control the gradient unit 5 by means of a gradient controller 5′ and the radiofrequency unit 7 by means of a radiofrequency transmit/receive controller 7′. The radiofrequency unit 7 can comprise a plurality of channels on which signals can be transmitted or received.

The radiofrequency unit 7, together with its radiofrequency transmit/receive controller 7′, may be configured for generating and applying (transmitting) an alternating RF field for manipulating the spins in a region to be manipulated (for example, in slices S to be measured) of the object under examination U. The center frequency of the alternating RF field, also known as the B1 field, is generally set as close as possible to the resonance frequency of the spins to be manipulated. Deviations of the center frequency from the resonance frequency are referred to as off-resonance. To generate the B1 field, controlled currents are applied to the RF coils in the radiofrequency unit 7 by means of the radiofrequency transmit/receive controller 7′.

In addition, the control facility 9 comprises a preparation control unit 15, with which the magnetization preparation blocks and preparation RF pulses can be determined which are implemented by the radiofrequency transmit/receive controller 7′ and the gradient controller 5′. Overall, the control facility 9 is designed to carry out any of the methods according to the disclosure.

A computing unit 13 incorporated in the control facility 9 is designed to carry out any of the computing operations required for the necessary measurements and determinations. Intermediate results and results required for this purpose or determined in the process can be stored in a memory unit S of the control facility 9. The units shown are not necessarily to be understood as physically separate entities, but rather as conceptual subdivisions that can also be implemented, for example, in fewer or even in a single physical unit.

Via an input/output device I/O of the magnetic resonance system 1, control commands can be sent to the magnetic resonance system, e.g. by a user, and/or results of the control facility 9, such as image data, can be displayed.

A method described herein can also be in the form of a computer program comprising instructions that execute the described method on a control facility 9. Similarly, a computer-readable storage medium can be provided which comprises instructions which, when executed by a control facility 9 of a magnetic resonance system 1, cause it to carry out the described method.

The various components described herein may be referred to as “units” or a “control facility.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units and/or control facilities, as applicable and relevant, may alternatively be referred to herein as “circuitry,” “controllers,” “processors,” or “processing circuitry,” or alternatively as noted herein.

Irrespective of the grammatical gender of a particular term, it is inclusive of persons with male, female or other gender identity.

What is claimed is:

1. A method for acquiring measurement data of an object under examination positioned in a magnetic resonance system using magnetic resonance with magnetization preparation, comprising:
performing a magnetization preparation block;
applying two preparation RF pulses;
performing, after the magnetization preparation block, an acquisition block comprising a further RF pulse;
acquiring, the acquisition block, two echo signals as respective measurement data,
wherein at least one of the two echo signals is generated by the two preparation RF pulses and the further RF pulse;
storing and/or further processing the acquired measurement data; and
generating a magnetic resonance image based upon the acquired measurement data.

2. The method as claimed in claim 1, wherein one of the two echo signals acquired as measurement data comprises an echo signal of a free induction decay generated by the further RF pulse.

3. The method as claimed in claim 1, wherein one of the two echo signals acquired as measurement data comprises an echo signal stimulated by the two preparation RF pulses and the further RF pulse.

4. The method as claimed in claim 1, further comprising:
determining, from the measurement data of the two acquired echo signals, a field map comprising one or more of (i) a B0 field map, (ii) a B1 field map, or (iii) a field map of a phase of a transmit-receive chain of the acquired measurement data.

5. The method as claimed in claim 4, further comprising:
performing, using the field map, contrast correction of image data reconstructed from the acquired measurement data.

6. The method as claimed in claim 5, wherein performing the contrast correction comprises performing the contrast correction on the image data reconstructed from the measurement data from which the field map was also determined.

7. The method as claimed in claim 1, further comprising:
determining (i) combined measurement from the measurement data of the two acquired echo signals, or (ii) combined image data from the image data reconstructed from the measurement data of the two acquired echo signals.

8. The method as claimed in claim 1, further comprising:
repeating the performing the magnetization preparation block, applying the two preparation RF pulses, performing the acquisition block, acquiring the two echo signals, and storing and/or further processing the acquired measurement data at least once to generate different respective magnetization preparation blocks.

9. The method as claimed in claim 1, wherein the magnetization preparation block comprises a Chemical Exchange Saturation Transfer (CEST) preparation block.

10. The method as claimed in claim 9, further comprising:
determining a CEST spectrum based upon the measurement data acquired with magnetization preparation blocks having different off-resonance saturation.

11. A magnetic resonance system, comprising:
a main magnet; and
a controller comprising a radiofrequency (RF) transmit/receive controller a preparation control unit,
wherein the controller is configured to acquire measurement data of an object under examination positioned in the magnetic resonance system using magnetic resonance with magnetization preparation by:
performing a magnetization preparation block;
applying two preparation RF pulses;
performing, after the magnetization preparation block, an acquisition block comprising a further RF pulse;
acquiring, the acquisition block, two echo signals as respective measurement data,
wherein at least one of the two echo signals is generated by the two preparation RF pulses and the further RF pulse;
storing and/or further processing the acquired measurement data; and
generating a magnetic resonance image based upon the acquired measurement data

12. A computer-readable storage medium comprising instructions that, when executed by a controller of a magnetic resonance system, cause the magnetic resonance system to acquire measurement data of an object under examination positioned in a magnetic resonance system using magnetic resonance with magnetization preparation by:
performing a magnetization preparation block;
applying two preparation RF pulses;
performing, after the magnetization preparation block, an acquisition block comprising a further RF pulse;
acquiring, the acquisition block, two echo signals as respective measurement data,
wherein at least one of the two echo signals is generated by the two preparation RF pulses and the further RF pulse;
storing and/or further processing the acquired measurement data; and
generating a magnetic resonance image based upon the acquired measurement data.
